(19) United States
(12) Patent Application Publication
(10) Pub. No.: US 2014/0264225 A1
(43) Pub. Date: Sep. 18, 2014

(54) RESISTANCE-VARIABLE MEMORY DEVICE

(71) Applicant: KABUSHIKI KAISHA TOSHIBA, Tokyo (JP)

(72) Inventor: Yusuke ARAYASHIKI, Kanagawa (JP)

(73) Assignee: KABUSHIKI KAISHA TOSHIBA, Tokyo (JP)

(21) Appl. No.: 14/016,180

(22) Filed: Sep. 2, 2013

(30) Foreign Application Priority Data
Mar. 15, 2013 (JP) 2013-054311

(51) Int. Cl. H01L 45/00

(52) U.S. Cl. CPC H01L 45/085
USPC 257/2

(57) ABSTRACT

According to one embodiment, a resistance-variable memory device that is suitable for miniaturization is provided. A resistance-variable memory device according to the embodiment comprises a resistance-variable layer, and an ion supply layer that is laminated on the resistance-variable layer and that contains a silver alloy. A silver concentration of the ion supply layer is in a range of 30-80 atom %.

### CROSS-REFERENCE TO RELATED APPLICATION

This application is based upon and claims the benefit of priority from Japanese Patent Application No. 2013-054311, filed Mar. 15, 2013, the entire contents of which are incorporated herein by reference.

### FIELD

Embodiments described herein relate to a semiconductor storage device that includes a variable resistance memory element to store data.

### BACKGROUND

In recent years, there has been proposed a variable resistance memory device that uses a varying resistance value to store data by causing a filament to appear or disappear by causing metal ions to diffuse in a high resistance layer. For this kind of variable resistance memory device, exemplified is a device structure that has, for example, a metal that is made from silver (Ag), and a variable resistance layer formed of silicon or silicon oxide film. However, the silver layer has low adhesion with resistance-variable layers of silicon or silicon oxide film and has a problem of causing film peeling and the like in the manufacturing process.

### DESCRIPTION OF THE DRAWINGS

FIG. 1 is a cross-sectional view that illustrates a memory element of a resistance-variable memory device according to a first embodiment.

FIG. 2 is a graphical representation that illustrates the effect of silver concentration in an ion supply layer on a measured initial leakage current in a resistance-variable memory device, according to an embodiment.

FIGS. 3A and 3B are schematic diagrams that illustrate a behavior when the ion supply layer is deposited on top of a variable resistance layer, according to an embodiment.

FIG. 4 is a graphical representation that illustrates the effects of the silver concentration in the ion supply layer on an operation of the memory element, according to an embodiment.

FIG. 5A is a graphical representation that illustrates an effect of a thickness of the ion supply layer on a switching element, according to an embodiment.

FIG. 5B is a graphical representation that illustrates the effect of the thickness of the ion supply layer on a set voltage, according to an embodiment.

FIG. 6 is a perspective view that illustrates a resistance-variable memory device according to a second embodiment.

FIG. 7 is a cross-sectional view that illustrates the resistance-variable memory device according to the second embodiment.

FIG. 8 is a cross-sectional view that illustrates a resistance-variable memory device according to the second embodiment.

### DETAILED DESCRIPTION

Embodiments provide a variable resistance memory device suitable for miniaturization.

In general, according to one embodiment, the embodiments of the present disclosure will be described with reference to the drawings.

The resistance-variable memory device, also referred to herein as a variable resistance memory device, according to the present embodiment comprises a resistance-variable layer, or variable resistance layer, and an ion supply layer that is laminated on, or deposited on, the resistance-variable layer. The ion supply layer may comprise a silver alloy that has a concentration in the range of 30-80 atom %.

First, a first embodiment of the present disclosure will be described.

FIG. 1 is a cross-sectional view that illustrates the memory element of the resistance-variable memory device according to the present embodiment.

As shown in FIG. 1, in memory elements 10 of a resistance-variable memory device 1 according to the embodiment of the present disclosure (hereafter simply will be referred to as “the device”), a lower electrode 11, a barrier metal layer 12, a resistance-variable layer 13, an ion supply layer 14, a barrier metal layer 15, and an upper electrode 16 are sequentially formed in this order on a substrate (e.g., silicon substrate 21 in FIG. 6). The lower electrode 11 and the upper electrode 16, for example, comprise tungsten (W). The lower electrode 11 and the upper electrode 16 may also be used as wires or may be provided separately from the wires. The barrier metal layers 12 and 15, for example, comprise titanium nitride (TiN), tantalum nitride (TaN), and/or tungsten nitride (WN).

The resistance-variable layer 13 is formed with a base material that has a high resistivity. In one example, the resistance-variable layer 13 is formed with silicon dioxide (SiO₂). The ion supply layer 14 is formed with a silver alloy, such as a silver titanium (Ag—Ti) alloy or a silver tantalum (Ag—Ta) alloy. The silver concentration in the ion supply layer 14 is in the range of 30-80 atom % and, preferably, in the range of 40-60 atom %. In addition, the thickness of the ion supply layer 14 is, for example, in the range of 3 to 20 nm (nanometers).

Next, the operations of the present embodiment will be described.

First, the basic memory operations of the memory element 10 will be described.

For the memory element 10, when applying a voltage in which the lower electrode 11 is made to be a negative electrode and the upper electrode 16 a positive electrode (hereafter referred to as “positive voltage”), some of the silver atoms contained in the ion supply layer 14 become positive ions by ionization. Thus, these positive ions move towards the lower electrode 11, which is a negative electrode, and enters the resistance-variable layer 13. Then, the positive ions are combined with electrons that are supplied from the lower electrode 11 within the resistance-variable layer 13 and precipitated as silver atoms. Through this, a filament (not shown) that is mainly composed of silver is formed so as to pass through the resistance-variable layer 13 within the resistance-variable layer 13 and the resistance-variable layer 13 becomes a “low resistance state”. This operation is referred to as the “set” state.

At the same time, for the memory element 10, when applying a voltage in which the lower electrode 11 is made to be a positive electrode and the upper electrode 16 a negative electrode (hereafter referred to as “reverse voltage”), the silver that forms the filament becomes positive ions through ionization and the positive ions move towards the upper electrode 16. Then, the positive ions are combined with electrons that are supplied from the upper electrode 16 within the ion supply layer 14 to return to the silver atoms. Through this, at least some of the filaments are lost and the resistance-variable layer 13 becomes a “high resistance state”. This operation is referred to as the “reset” state.

Next, the operations by forming the ion supply layer 14 with the silver alloy will be described.

When forming the ion supply layer 14 with the silver alloy, the ion supply layer 14 becomes difficult to aggregate even though thinning the ion supply layer 14, compared with when forming with pure silver. For example, when a thin pure silver layer that has a thickness of less than 20 nm is formed, the silver tends to aggregate to form islands that have a periodicity of several tens of nanometers (nm) according to the formation conditions. For this reason, when the diameter of the memory element 10 is miniaturized to less than several tens of nm, there are cases in which the ion supply layer 14 in a portion of the memory element 10 is not formed. On the other hand, because the ion supply layer 14 is formed with a silver alloy in the present embodiment, aggregation is suppressed and therefore, even if the memory element 10 is miniaturized, the ion supply layer 14 is reliably formed. In other words, it is possible to make the ion supply layer 14 thin in the memory element 10 using the techniques described herein. By use of the techniques described herein, the ability to form a memory element 10 that has desirable properties and size is improved.

In addition, since the silver alloy suppresses aggregation when compared with pure silver, a uniform and good film formation can be implemented through a conformal deposition process in a place that has a gap, or a metal deposition process in a hole formed in a damascene structure or within a trench.

Furthermore, by forming the ion supply layer 14 with a silver alloy, good adhesion to the resistance-variable layer 13 and the barrier metal layer 15 is exhibited compared with the case of forming a layer with pure silver. As a result, together with improving the workability of the memory element 10, the reliability of the resistance-variable memory device 1 is also improved.

Moreover, by forming the ion supply layer 14 with a silver alloy, the leakage current at the initial state is decreased compared with the case of forming with pure silver.

FIG. 2 is a graphical representation that illustrates the effects of the silver concentration in the ion supply layer that is deposited by a sputtering method on the initial leakage current, with the silver concentration in the ion supply layer on the horizontal axis and the size of the leakage current in its initial state on the vertical axis.

As shown in FIG. 2, the initial leakage current becomes smaller the lower the silver concentration of the ion supply layer 14 is. Specifically, when the silver concentration in the ion supply layer 14 goes from 80 atom % to 50 atom %, the size of the initial leakage current rapidly decreases. Consequently, in order to obtain the effect of decreasing the initial leakage current, it is preferable for the silver concentration in the ion supply layer 14 to be less than 80 atom %.

The reason that the initial leakage current becomes smaller the lower the silver concentration of ion supply layer 14 is not necessarily clear, but not intending to be limited by the theory described herein, it is thought to occur as follows.

FIGS. 3A and 3B are schematic diagrams that illustrate the behavior when the ion supply layer is deposited on top of the variable resistance layer. FIG. 3A illustrates the effect of forming the ion supply layer with pure silver. FIG. 3B illustrates the effect of forming the ion supply layer with a silver alloy.

As shown in FIG. 3A, when the silver is deposited on the resistance-variable layer 13 that is composed of silicon oxide, because the silver does not readily bind to silicon and oxygen, the silver atoms that are accelerated towards the surface of the resistance-variable layer 13 during a film deposition process, such as a plasma deposition process (e.g., sputtering process, etc.), do not stop at the surface of the resistance-variable layer 13 and are implanted into the resistance-variable layer 13. As a result, the resistance-variable layer 13 contains an amount of the silver after the deposition process, thus the initial leakage current of the element is increased.

On the other hand, as shown in FIG. 3B, when silver and titanium are deposited at the same time on the resistance-variable layer 13 composed of silicon oxide, the titanium atoms that are sputtered are readily combined with silicon and oxygen, and stop near the surface of the resistance-variable layer 13. Because of this, the amounts of titanium atoms that are implanted are considered to be low as compared with the silver. Furthermore, the titanium atoms combine with silicon and oxygen atoms to stably exist around the surface of the resistance-variable layer 13, and thereby act as barrier against the implantation of silver atoms into the resistance-variable layer 13. Because of this, the amount of silver that penetrates into the resistance-variable layer 13 is decreased, and the leakage current of the variable resistance layer 13 is kept low.

Furthermore, by reducing the leakage current of the resistance-variable layer 13, there also exists the benefits of allowing a thin resistance-variable layer 13 to be used. When the resistance-variable layer 13 is thinned, while the aspect ratio of the device is reduced to make the processing of the memory element 10 easier, the driving voltage of the device 1 can be decreased by decreasing the voltage required to operate the device.

It should be noted that, while not shown in the drawings, the set voltage of the memory element 10 does not change much, although the silver concentration in the ion supply layer 14 changed. It should also be noted that the “set voltage” is the voltage necessary in order to generate the set operations described above.

On the other hand, changing the material of the ion supply layer 14 from pure silver to a silver alloy also triggers new problems to be solved. In the paragraphs that follow, these problems and the methods for solving them will be described.

One of the problems is the decrease of the switching probability of the memory element 10.

FIG. 4 is a graphical representation that illustrates the effects of the silver concentration in the ion supply layer on the operation of the memory element, with the silver concentration in the ion supply layer on the horizontal axis and the switching probability of the memory element on the vertical axis.

It should be noted that the switching probability that will be described herein is a numerical value that is obtained by dividing the number of elements in which the set operation were carried out when a constant voltage was applied for a certain period of time by the number of elements having been evaluated, and the switching probability is one indicator which evaluates whether or not switching operations can be stably generated under a constant voltage with the element structure. Furthermore, the values shown on the vertical axis of FIG. 4 are relative values that define 100% of the switching probability when the ion supply layer is formed with pure silver.

As shown in FIG. 4, when the silver concentration in the ion supply layer 14 is lowered, the switching probability of the memory element 10 decreases. However, when the silver concentration is more than 30 atom %, a part of memory element 10 switches. Furthermore, when the silver concentration is more than 40 atom %, greater than 50% of the memory elements 10 switch compared with the case where an ion supply layer is formed with pure silver. Therefore, it is possible to suppress the switching probability from being decreased by making the silver concentration in the ion supply layer 14 to be greater than 30 atom %, or preferably greater than 40 atom %, in the present embodiment. FIG. 4 shows both cases when the ion supply layer 14 is formed with a silver titanium alloy (Ag—Ti alloy), and when the ion supply layer 14 is formed with a silver tantalum alloy (Ag—Ta alloy), but the differences in the switching probability behavior of an Ag—Ti alloy and the behavior of an Ag—Ta alloy are not observed.

In this way, the leakage characteristics and switching characteristics with regard to the silver concentration in the ion supply layer 14 have a trade-off relationship, but because the switching probability is expected to improve through measures of thinning the resistance-variable layer 13 and the like, the silver concentration in the ion supply layer 14 is preferred to be in the range of 40-60 atom %.

Next, the operations by setting the thickness of the ion supply layer 14 to 3-20 nm will be described.

FIG. 5A is a graphical representation that illustrates the effect of the thickness of the ion supply layer on the switching element, with the thickness, or amount of film deposition, of the ion supply layer on the horizontal axis and the switching probability of the memory element on the vertical axis. FIG. 5B is a graphical representation that illustrates the effect of the thickness of the ion supply layer on the set voltage, with the amount of film deposition of the ion supply layer on the horizontal axis and the set voltage of the memory element on the vertical axis.

The data shown in FIGS. 5A and 5B are the data when the ion supply layer 14 is formed with pure silver. It should be noted that the values shown on the vertical axis of FIGS. 5A and 5B are relative values that are set to 1 in cases where the deposition amount of the ion supply layer 14 is 3 nm.

As shown in FIGS. 5A and 5B, when the deposition amount of the ion supply layer 14 is less than 3 nm, the switching probability of the memory element 10 decreases and a tendency of the magnitude of set voltage to increase is observed. On the other hand, when the deposition amount is over 3 nm, the switching probability and set voltage are stable regardless of the deposition amount. Therefore, it is preferable for the thickness of the ion supply layer 14 to be more than 3 nm. On the other hand, it is preferable for the thickness of the ion supply layer 14 to be less than 20 nm from the viewpoint of the workability and cost to produce the memory element 10.

Next, the effect of the present embodiment will be explained.

In the present embodiment, the ion supply layer 14 is formed with silver alloy instead of pure silver, so it is possible to suppress aggregation at the time of deposition, and to form a thin ion supply layer 14. As a result, the workability of the memory element 10 can be improved. In addition, the adhesion of the ion supply layer 14 can also be improved. For this reason, the workability of the memory element 10 can be further improved, and at the same time, the reliability of the resistance-variable memory device 1 can be improved.

Furthermore, it is possible to decrease the initial leakage current by setting the silver concentration in the ion supply layer 14 to be 80 atom % or less. It is preferable for the silver concentration in the ion supply layer 14 to be less than 60 atom %. On the other hand, it is possible to ensure the switching characteristics of the memory element 10 by setting the silver concentration in the ion supply layer 14 to be greater than 30 atom %. It is preferable for the silver concentration to be higher than 40 atom %. Moreover, by having the thickness of the ion supply layer 14 to be from 3 to 20 nm in one embodiment, while maintaining the switching probability of the memory element 10 and a set current in a good state, it is also possible to achieve good workability of the device.

It should be noted that the materials for configuring each part of the memory element of the present embodiment are not limited to the examples given above. Suitable materials for each part are enumerated below.

As for the metals that are combined with silver in the silver alloy that forms the ion supply layer 14, for example, one or more metals selected from the group consisting of: titanium (Ti), tantalum (Ta), hafnium (Hf), tungsten (W), molybdenum (Mo), palladium (Pd), copper (Cu), aluminum (Al), cobalt (Co), nickel (Ni), iridium (Ir), zinc (Zr), iron (Fe), ruthenium (Ru), niobium (Nb), zirconium (Zr), chromium (Cr), and yttrium (Y) may be used.

As for the materials that form the resistance-variable layer 13, for example, materials that contain silicon such as amorphous silicon (a-Si), poly silicon (poly-Si), silicon dioxide (SiO₂), silicon nitride (Si₃N₄), silicon oxynitride (SiON), etc., and transition metal oxides, such as hafnium oxide (HfOx), hafnium silicon oxide (HfSiOx), hafnium silicon oxynitride (HfSiON), aluminum oxide (AlOx), hafnium aluminum oxide (HfAlOx), zirconium oxide (ZrOx), etc may be used.

Next, a second embodiment will be described.

FIG. 6 is a perspective view that illustrates a resistance-variable memory device according to the second embodiment.

FIG. 7 is a cross-sectional view that illustrates the resistance-variable memory device according to the second embodiment.

The present embodiment is an example that integrates the memory element described in the first embodiment into a cross-point type.

As shown in FIG. 6, a silicon substrate 21 is provided in a resistance-variable memory device 2 according to the present embodiment, and the drive circuit of the device 2 (not shown) is formed in the upper layer portion and the upper surface of the silicon substrate 21. An interlayer insulating film 22 composed of, for example, silicon oxide is provided on the silicon substrate 21 so as to embed the drive circuit and a memory cell section 23 is provided on the top of the interlayer insulating film 22.

The word lines wiring layer 24 that includes a plurality of word lines WL that extend in a direction parallel to the top surface of the silicon substrate 21 (hereafter referred to as “word lines direction”), and the bit lines wiring layer 25 that includes a plurality of bit lines BL that extend in a direction intersecting the word lines direction, that is, for example, perpendicular direction (hereafter referred to as “bit lines direction”), the direction being parallel to the top surface of the silicon substrate 21 are alternately laminated in the memory cell section 23. Word lines WL and bit lines BL are not in contact with each other.

Thus, pillars 26a and 26b extending in a vertical direction against the top surface of the silicon substrate 21 (hereafter referred to as “vertical direction”) are provided in closest contact points of each of the word lines WL and each of the bit lines BL. The pillar 26a is a pillar where bit lines BL are positioned on the upper side and the word lines WL are positioned on the lower side. The pillar 26b is a pillar where word lines WL are positioned on the upper side and the bit lines BL are positioned on the lower side. Hereinafter, the pillars 26a and 26b are also collectively referred to as pillars 26.

The shape of the pillars 26 are, for example, a cylindrical shape, rectangular column shape, or substantially rectangular column shape of which corners are rounded, and a diameter of the pillar is, for example, about 20 nm. The pillars 26 are formed between the word lines WL and bit lines BL and one memory element is composed through one of the pillars 26. An interlayer insulating film 27 (refer to FIG. 7) is embedded between word lines WL, bit lines BL, and pillars 26 to isolate theses conductive elements from each other.

The configuration of pillars 26 will be described below.

As shown in FIG. 7, the following layers are laminated in the following order toward the upper layer side (bit lines BL side) from the lower layer side (word lines WL side) in the pillar 26a: the barrier metal layer 12, the resistance-variable layer 13, the ion supply layer 14, the barrier metal layer 15, and the stopper layer 17. The stopper layer 17 functions as a CMP (chemical mechanical polishing) etch stop. At the same time, the following layers are laminated in the following order towards the upper layer side (word lines WL side) from the lower layer side (bit lines BL side) in the pillar 26b: the barrier metal layer 12, the ion supply layer 14, the resistance-variable layer 13, the barrier metal layer 15, and the stopper layer 17.

In this way, the resistance-variable layer 13 and the ion supply layer 14 are serially connected in between each of the word lines WL and each of the bit lines BL. However, the arrangement sequence of the resistance-variable layer 13 is different from that of the ion supply layer 14 in the pillar 26a and the pillar 26b, and the ion supply layer 14 are positioned on the bit lines BL side of the resistance-variable layer 13. In other words, the ion supply layer 14 is connected in between bit lines BL and the resistance-variable layer 13. The composition of each layer described above is the same as the previously mentioned in the first embodiment.

Next, the effects of the present embodiment will be described.

In the present embodiment, the memory element is able to be arranged three dimensionally by making the memory cell section 23 a cross-point structure. As a result, the storage density increases.

However, when manufacturing the device 2, in the pillar 26b, it is necessary to form the resistance-variable layer 13 above the ion supply layer 14. Provisionally, when the ion supply layer 14 is formed with pure silver, because the reactivity of the silver is high and unstable, an aggregation and diffusion of silver occur on the surface of the resistance-variable layer 13 during the deposition of the resistance-variable layer 13, and it is highly possible that the desired pillar shape and/or layered composition will not be achieved. On the other hand, because the ion supply layer 14 is formed with a silver alloy according to the present embodiment, the aggregation of the ion supply layer 14 is suppressed and the ion supply layer 14 has a higher heat resistance. Because of this, it is easy to process the pillar 26b into a desired shape and layered composition.

Configurations, operations, and effects of the present embodiment other than those mentioned above are the same as the first embodiment described earlier. It should also be noted that the structure of the memory cell in the cross-point-type resistance-variable memory device is not limited to the pillar shape. For example, the resistance-variable layer 13 could also be a continuous film that is spread on the word lines direction and the bit lines direction.

Next, a third embodiment will be described.

FIG. 8 is a cross-sectional view that illustrates the resistance-variable memory device according to the third embodiment.

As shown in FIG. 8, a silicon substrate 31 is provided in a resistance-variable memory device 3 according to the present embodiment, and a plurality of word lines WL are provided above the silicon substrate 31. The word lines WL extend in a direction of Y and are arranged in a matrix along X and Z directions. It should also be noted that the X, Y, and Z directions are mutually perpendicular; the Z direction is a direction vertical with respect to the upper surface of silicon substrate 31. The word lines WL are formed with a silver alloy, such as a silver alloy having a silver concentration in the range of 30-80 atom %. In one example, the silver concentration in the formed word line is between 40 and 60 atom %.

Furthermore, a plurality of bit lines BL are also provided above the silicon substrate 31. The bit lines BL extends in the Z direction and are arranged in a matrix along the X and Y directions. In addition, the resistance-variable layer 13 extending in the Z direction is provided in between each of the word lines WL and each of the bit lines BL. The interlayer insulating film 27 is provided in between word lines WL and bit lines BL.

Next, operations and effects of the present embodiment will be described.

In the present embodiment, the word lines WL that are composed of a silver alloy function as an ion supply layer for the resistance-variable layer 13.

Thus, because the word lines WL are formed with a silver alloy in the present embodiment, it is possible to decrease the wiring resistance of the word lines WL. Furthermore, when the bit lines BL are formed, it is necessary to process the word lines WL, but because the word lines WL are formed with a silver alloy and not with pure silver, reactivity and agglomerating property of the word lines WL are low and processing thereof is easy. Furthermore, it is also possible for the word lines WL to be formed using a damascene process.

Configurations, operations, and effects other than those described above in the present embodiment are the same as the above-mentioned first embodiment.

According to the embodiment described above, it is possible to achieve a resistance-variable memory device that is suitable for miniaturization.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance-variable memory device, comprising:
a first wiring layer composed of a plurality of first wires extending in a first direction;
a second wiring layer composed of a plurality of second wires extending in a second direction that intersects the first direction, wherein the first wiring layer and the second wiring layer are alternately formed over a substrate; and
a pillar disposed between each of the first wires and each of the second wires,
wherein the pillar comprises
a resistance-variable layer comprising silicon, and
an ion supply layer that is disposed between the second wires and the resistance-variable layer, and comprises silver and an element selected from a group consisting of titanium and tantalum, and
wherein a concentration of silver in the ion supply layer is between 40 and 60 atom %.

2. The resistance-variable memory device of claim 1, wherein the resistance-variable layer further comprises silicon and oxygen.

3. The resistance-variable memory device of claim 1, wherein the resistance-variable layer comprises one or more materials selected from a group consisting of silicon, silicon oxide, silicon nitride, silicon oxynitride, hafnium oxide, hafnium silicon oxide, hafnium silicon oxynitride, aluminum oxide, hafnium aluminum oxide and zirconium oxide

4. The resistance-variable memory device of claim 1, wherein a thickness of the ion supply layer is between 3 and 20 nm.

5. A resistance-variable memory device, comprising:
a resistance-variable layer; and
an ion supply layer that is formed on the resistance-variable layer, and comprises silver and at least one additional element, wherein a concentration of silver in the ion supply layer is between 30 and 80 atom %.

6. The resistance-variable memory device of claim 5, wherein the at least one additional element comprises an element selected from a group consisting of titanium (Ti), tantalum (Ta), hafnium (Hf), tungsten (W), molybdenum (Mo), palladium (Pd), copper (Cu), aluminum (Al), cobalt (Co), nickel (Ni), iridium (Ir), zinc (Zr), iron (Fe), ruthenium (Ru), niobium (Nb), zirconium (Zr), chromium (Cr) and yttrium (Y).

7. The resistance-variable memory device of claim 5, wherein the silver concentration in the ion supply layer is between 40 and 60 atom %.

8. The resistance-variable memory device of claim 5, wherein the resistance-variable layer further comprises silicon and oxygen.

9. The resistance-variable memory device of claim 5, wherein a thickness of the ion supply layer is between 3 and 20 nm.

10. The resistance-variable memory device of claim 5, wherein the at least one additional element comprises an element selected from a group consisting of titanium (Ti) and tantalum (Ta).

11. The resistance-variable memory device of claim 5, further comprising:
a first wiring layer composed of a plurality of first wires extending in a first direction; and
a second wiring layer composed of a plurality of second wires extending in a second direction that intersects the first direction,
wherein the resistance-variable layer and the ion supply layer are serially connected between each of the first wires and each of the second wires, and
the ion supply layer is disposed between the second wires and the resistance-variable layer.

12. A resistance-variable memory device, comprising:
a substrate;
a plurality of first wires that comprise silver and at least one additional element, wherein the plurality of first wires extend in a first direction and are arranged along a second direction and a third direction, wherein the first and second directions are both parallel to an upper surface of the substrate, the second direction intersects the first direction, and the third direction is perpendicular to the upper surface;
a plurality of second wires that extends in the third direction, wherein the plurality of second wires are arranged along the first direction and the second direction; and
a resistance-variable layer disposed between each of the first wires and each of the second wires,
wherein a concentration of silver in the first wires is between 30 and 80 atom %.

13. The resistance-variable memory device of claim 12, wherein the concentration of silver in the first wires is between 40 and 60 atom %.

14. The resistance-variable memory device of claim 12, wherein the at least one element is selected from a group consisting of titanium, tantalum, hafnium, tungsten, molybdenum, palladium, copper, aluminum, cobalt and nickel.

15. The resistance-variable memory device of claim 12, wherein the resistance-variable layer comprises one or more materials selected from a group consisting of silicon, silicon oxide, silicon nitride, silicon oxynitride, hafnium oxide, hafnium silicon oxide, hafnium silicon oxynitride, aluminum oxide, hafnium aluminum oxide and zirconium oxide.

16. The resistance-variable memory device of claim 12, wherein a thickness of the ion supply layer is between 3 and 20 nm.

17. The resistance-variable memory device of claim 12, wherein the resistance-variable layer further comprises silicon and oxygen.

18. The resistance-variable memory device of claim 12, wherein the at least one additional element comprises an element selected from a group consisting of titanium (Ti) and tantalum (Ta).
